(19) United States
(12) Patent Application Publication
(10) Pub. No.: US 2026/0143673 A1
(43) Pub. Date: May 21, 2026

(54) SEMICONDUCTOR DEVICE INCLUDING ACTIVE PATTERN AND GATE ELECTRODE

(71) Applicant: Samsung Electronics Co., Ltd., Suwon-si (KR)

(72) Inventors: Hosang Lee, Suwon-si (KR); Taejin Park, Suwon-si (KR)

(21) Appl. No.: 19/231,247

(22) Filed: Jun. 6, 2025

(30) Foreign Application Priority Data
Nov. 20, 2024 (KR) 10-2024-0166104

(51) Int. Cl. H10B 12/00; H10D 89/10

(52) U.S. Cl. CPC H10B 12/315; H10D 89/10

(57) ABSTRACT

An example semiconductor device includes a first cell active pattern and a first dummy active pattern, arranged in a first horizontal direction; a first gate electrode adjacent to the first cell active pattern and the first dummy active pattern; a first cell gate dielectric layer between the first cell active pattern and the first gate electrode, and a first dummy gate dielectric layer between the first dummy active pattern and the first gate electrode; a first gate contact plug contacting the first dummy active pattern and the first gate electrode; and a bit line disposed at a lower level than the first cell active pattern, connected to the first cell active pattern, and spaced apart from the first dummy active pattern.

### CROSS-REFERENCE TO RELATED APPLICATION

This application claims priority to Korean Patent Application No. 10-2024-0166104 filed on Nov. 20, 2024, in the Korean Intellectual Property Office, the disclosure of which is incorporated herein by reference in its entirety.

### BACKGROUND

Research is being conducted to reduce sizes of elements constituting a semiconductor device and to improve performance thereof. For example, in a DRAM, research is being conducted to reliably and stably form elements with reduced sizes. As sizes of the elements are reduced, dispersion characteristics of the semiconductor device may be deteriorating.

### SUMMARY

The present disclosure relates to a semiconductor device capable of increasing a degree of integration and improving performance, and a method for forming the semiconductor device.

In some implementations, a semiconductor device includes a first cell active pattern and a first dummy active pattern, arranged in a first horizontal direction; a first gate electrode adjacent to the first cell active pattern and the first dummy active pattern; a first cell gate dielectric layer between the first cell active pattern and the first gate electrode, and a first dummy gate dielectric layer between the first dummy active pattern and the first gate electrode; a first gate contact plug contacting the first dummy active pattern and the first gate electrode; and a bit line disposed at a lower level than the first cell active pattern, connected to the first cell active pattern, and spaced apart from the first dummy active pattern.

In some implementations, a semiconductor device includes a memory cell array region and an interface region, adjacent to each other in a first horizontal direction; gate electrodes extending in the first horizontal direction, crossing the memory cell array region, and extending into the interface region; active patterns including cell active patterns disposed in the memory cell array region and arranged along the first horizontal direction and a second horizontal direction, perpendicular to the first horizontal direction, and dummy active patterns disposed in the interface region and arranged along the second horizontal direction; gate dielectric layers interposed between the gate electrodes and the active patterns; bit lines extending in the second horizontal direction, crossing the memory cell array region, and connected to the cell active patterns below the cell active patterns; and gate contact plugs disposed in the interface region, wherein the active patterns penetrate the gate electrodes in a vertical direction, perpendicular to the first and second horizontal directions, a first gate electrode of the gate electrodes is adjacent to a first dummy active pattern, of the dummy active patterns, and a first gate contact plug of the gate contact plugs vertically overlaps the first dummy active pattern, and is in contact with the first gate electrode.

In some implementations, a semiconductor device includes a memory cell array region and an interface region, adjacent to each other in a first horizontal direction; gate electrodes extending in the first horizontal direction, crossing the memory cell array region, and extending into the interface region; bit lines extending in a second horizontal direction, perpendicular to the first horizontal direction, and crossing the memory cell array region; active patterns penetrating the gate electrodes in a vertical direction, perpendicular to the first and second horizontal directions, and including cell active patterns disposed in the memory cell array region and dummy active patterns disposed in the interface region; gate dielectric layers between the active patterns and the gate electrodes; and gate contact plugs connected to the gate electrodes, wherein the dummy active patterns include a first dummy active pattern and a second dummy active pattern, adjacent to each other in the second horizontal direction, the first dummy active pattern has a length in the first horizontal direction greater than a length of each of the cell active patterns in the first horizontal direction, the length of the first dummy active pattern in the first horizontal direction is greater than a length of the second dummy active pattern in the first horizontal direction, and a first gate contact plug of the gate contact plugs is in contact with a first gate electrode of the gate electrodes.

### BRIEF DESCRIPTION OF THE DRAWINGS

The aspects, features, and advantages of the present disclosure will be more clearly understood from the following detailed description, taken in conjunction with the accompanying drawings.

FIGS. 1, 2, and 3 are views illustrating an example of a semiconductor device.

FIG. 4 is a schematic perspective view illustrating an example of a semiconductor device.

FIGS. 5A, 5B, 6A, and 6B are views illustrating examples of a semiconductor device.

FIG. 7 is a cross-sectional view illustrating an example of a semiconductor device.

FIG. 8 is a cross-sectional view illustrating an example of a semiconductor device.

FIG. 9 is a cross-sectional view illustrating an example of a semiconductor device.

FIG. 10 is a cross-sectional view illustrating an example of a semiconductor device.

FIG. 11 is a cross-sectional view illustrating an example of a semiconductor device.

FIG. 12 is a cross-sectional view illustrating an example of a semiconductor device.

FIG. 13 is a plan view illustrating an example of a semiconductor device.

FIGS. 14A and 14B are views illustrating an example of a semiconductor device.

FIG. 15 is a plan view illustrating an example of a semiconductor device.

FIGS. 16A, 16B, 17A, 17B, 18A, 18B, 19A, 19B, 20A, 20B, 21A, and 21B are cross-sectional views illustrating an example of a method for forming a semiconductor device.

### DETAILED DESCRIPTION

Hereinafter, terms such as “upper,” “intermediate,” “lower,” and the like may be replaced with other terms, for example, terms such as “first,” “second,” “third,” and the like, and may be used to describe elements of the specification. Terms such as “first,” “second,” “third,” and the like may be used to describe various elements, but the elements are not limited by the terms, and the “first element” may be referred to as the “second element.” In the specification, terms such as “lower portion,” “upper portion,” “upper end,” “lower end,” and the like may be terms described based on the drawings.

In the specification, among active patterns, an active pattern electrically connected to a bit line and a data storage structure may be defined as a cell active pattern, and an active pattern not electrically connected to a bit line and a data storage structure may be defined as a dummy active pattern.

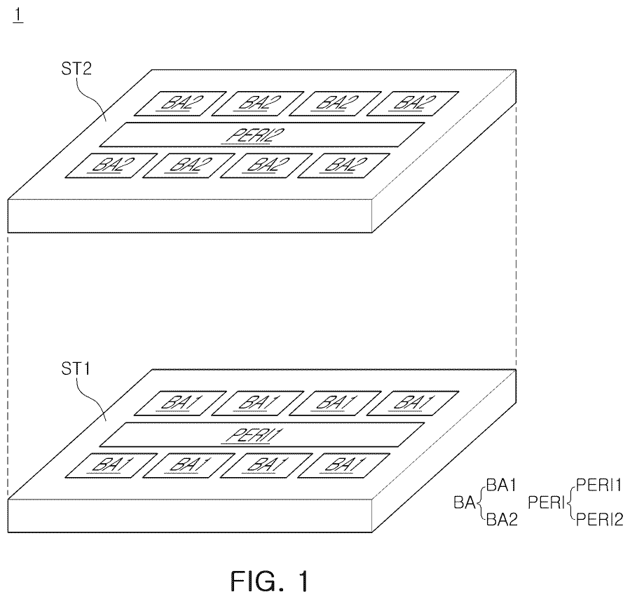

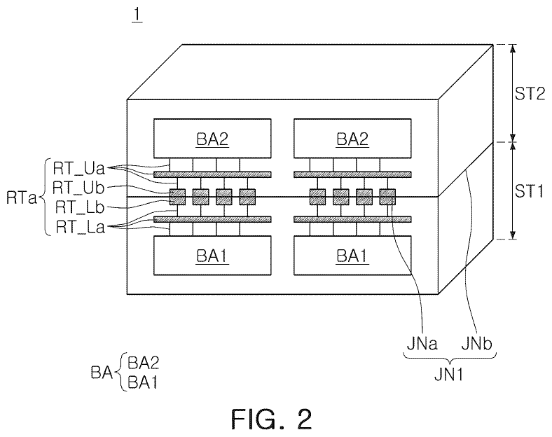

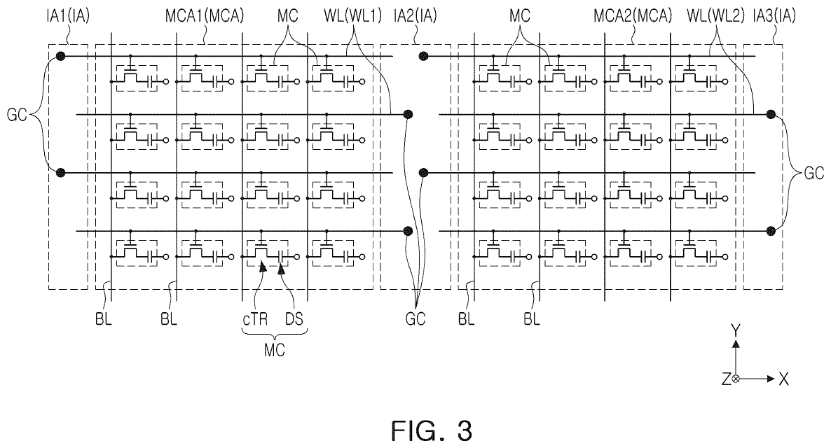

Referring to FIGS. 1, 2, and 3, an example of a semiconductor device 1 will be described. In FIGS. 1, 2, and 3, FIG. 1 is a perspective view conceptually illustrating a semiconductor device 1, FIG. 2 is a perspective view conceptually illustrating an electrical connection relationship between first and second structures ST1 and ST2 of FIG. 1, and FIG. 3 is a circuit diagram illustrating a circuit of a portion of a first structure ST1.

Referring to FIGS. 1, 2, and 3, a semiconductor device 1 may include a first structure ST1 and a second structure ST2 vertically overlapping the first structure ST1. The second structure ST2 may be disposed on the first structure ST1. In some implementations, the second structure ST2 may be disposed below the first structure ST1.

In some implementations, the first structure ST1 may be a first chip structure including memory cells MC (FIG. 3), and the second structure ST2 may be a second chip structure including peripheral circuits such as a sense amplifier, a sub-word line driver, or the like, used for operations of the memory cells MC.

In some implementations, the first structure ST1 and the second structure ST2 may be formed by being bonded by a bonding process such as a wafer bonding process. For example, the first structure ST1 may be in contact with and bonded to the second structure ST2.

The semiconductor device 1 may include a plurality of banks BA and an outer peripheral region PERI.

The outer peripheral region PERI may include a first peripheral region PERI1 in the first structure ST1, and a second peripheral region PERI2 in the second structure ST2. The outer peripheral region PERI may be a peripheral region in which peripheral circuits for input/output of data or commands, or input of power/ground, are disposed.

Each of the plurality of banks BA may include a first bank region BA1 in the first structure ST1 and a second bank region BA2 in the second structure ST2.

The first bank region BA1 in the first structure ST1 may include memory cell array regions MCA (FIG. 3) and interface regions IA (FIG. 3). The memory cell array regions MCA and the interface regions IA may be adjacent to each other in a first horizontal direction X. For example, the memory cell array regions MCA and the interface regions IA may include a first interface region IA1, a first memory cell array region MCA1, a second interface region IA2, a second memory cell array region MCA2, and a third interface region IA3, sequentially disposed in the first horizontal direction X.

The first bank region BA1 in the first structure ST1 may include the memory cells MC (FIG. 3), word lines WL (FIG. 3), and bit lines BL (FIG. 3).

The memory cells MC may be disposed in the memory cell array region MCA. Each of the word lines WL may extend in the first horizontal direction X. The word lines WL may cross the memory cell array regions MCA, may be electrically connected to the memory cells MC, and may extend into the interface regions IA adjacent to the memory cell array regions MCA. For example, first word lines WL1 of the word lines WL may cross the first memory cell array region MCA1, and may extend into the first and second interface regions IA1 and IA2. Second word lines WL2 of the word lines WL may cross the second memory cell array region MCA2, and may extend into the second and third interface regions IA2 and IA3.

The first structure ST1 may include gate contact plugs GC electrically connected to the word lines WL in the interface regions IA.

The bit lines BL may cross the memory cell array regions MCA in a second horizontal direction Y, perpendicular to the first horizontal direction X, and may be electrically connected to the memory cells MC.

Each of the memory cells MC may include a data storage structure DS that may serve as data storage, and a cell transistor cTR that may be electrically connected to the data storage structure DS. In a memory such as a DRAM, the data storage structure DS may be a cell capacitor that may store data.

The second bank region BA2 in the second structure ST2 may include peripheral circuits such as a sense amplifier electrically connected to the bit lines BL in the memory cell array region MCA, a sub-word line driver electrically connected to the word lines WL in the memory cell array region MCA, or the like.

The first and second structures ST1 and ST2 may further include a routing interconnection structure RTa electrically connecting the first bank region BA1 and the second bank region BA2. For example, the routing interconnection structure RTa may include a first routing interconnection structure RT_La and RT_Lb disposed in the first structure ST1, and a second routing interconnection structure RT_Ua and RT_Ub disposed in the second structure ST2.

The first routing interconnection structure RT_La and RT_Lb may include a first interconnection structure RT_La electrically connected to the first bank region BA1, and first bonding pads RT_Lb electrically connected to the first interconnection structure RT_La. The second routing interconnection structure RT_Ua and RT_Ub may include a second interconnection structure RT_Ua electrically connected to the second bank region BA2, and second bonding pads RT_Ub electrically connected to the second interconnection structure RT_Ua.

The first bonding pads RT_Lb and the second bonding pads RT_Ub may be in contact with each other and bonded. For example, the first bonding pads RT_Lb and the second bonding pads RT_Ub may include copper, and may be bonded to each other by an inter-metal bonding process. Therefore, a bonding surface JN1 between the first structure ST1 and the second structure ST2 may include intermetallic bonding regions JNa in which the first bonding pads RT_Lb of the first structure ST1 and the second bonding pads RT_Ub of the second structure ST2 are bonded to each other, and interdielectric bonding regions JNb in which a dielectric of the first structure ST1 and a dielectric of the second structure ST2 are bonded to each other.

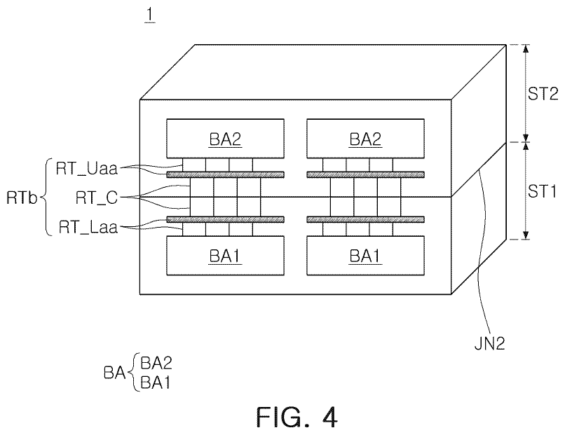

Next, an example of the routing interconnection structure RTa and the bonding surface JN1 will be described with reference to FIG. 4. FIG. 4 is a schematic perspective view illustrating an example of the routing interconnection structure RTa and the bonding surface JN1 in FIG. 2.

In an example, referring to FIG. 4, the routing interconnection structure RTa in FIG. 2 may be replaced with a routing interconnection structure RTb in which the first bonding pads RT_Lb and the second bonding pads RT_Ub may be omitted, and the bonding surface JN1 in FIG. 2 may be replaced with a bonding surface JN2 in which the intermetallic bonding regions JNa may be omitted.

The routing interconnection structure RTb may include a first interconnection structure RT_Laa included in the first structure ST1 and electrically connected to the first bank region BA1, a second interconnection structure RT_Uaa included in the second structure ST2 and electrically connected to the second bank region BA2, and a connection structure RT_C extending from the first structure ST1 to the second structure ST2 and electrically connecting the first and second interconnection structures RT_Laa and RT_Uaa. The bonding surface JN2 between the first structure ST1 and the second structure ST2 may be formed as a dielectric bonding surface in which the dielectric of the first structure ST1 and the dielectric of the second structure ST2 are bonded to each other. The connection structure RT_C may include a through-via or a through connection plug, capable of penetrating the bonding surface JN2.

Hereinafter, examples of the first structure ST1 of the semiconductor device 1 will be described together with FIGS. 1 to 3. Hereinafter, examples of the first structure ST1 of the semiconductor device 1 described in FIGS. 1 to 3 will be described, but in example implementations described below, the routing interconnection structure RTa and the bonding surface JN1 described in FIG. 3 may be replaced with the routing interconnection structure RTb and the bonding surface JN2 described in FIG. 4. In addition, example implementations described below may be combined with each other to form an example implementation.

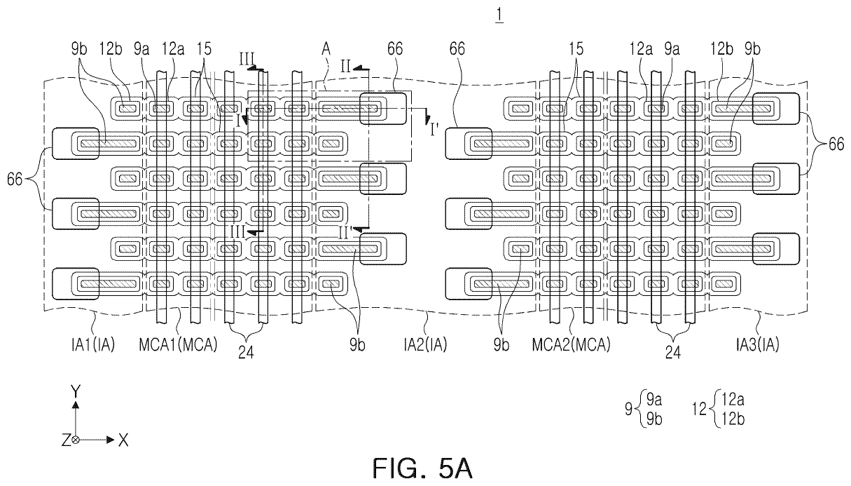

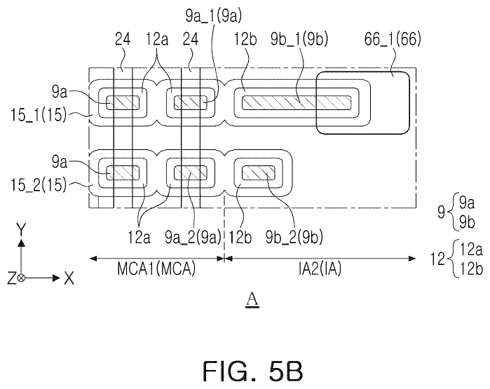

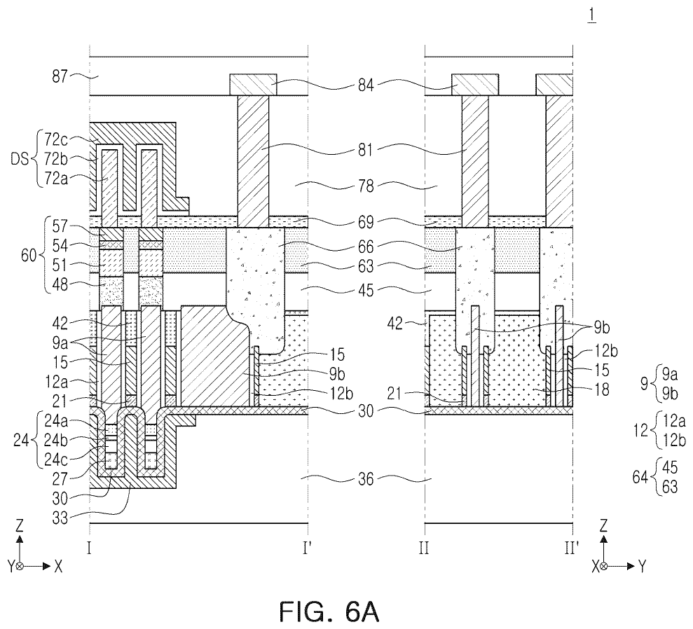

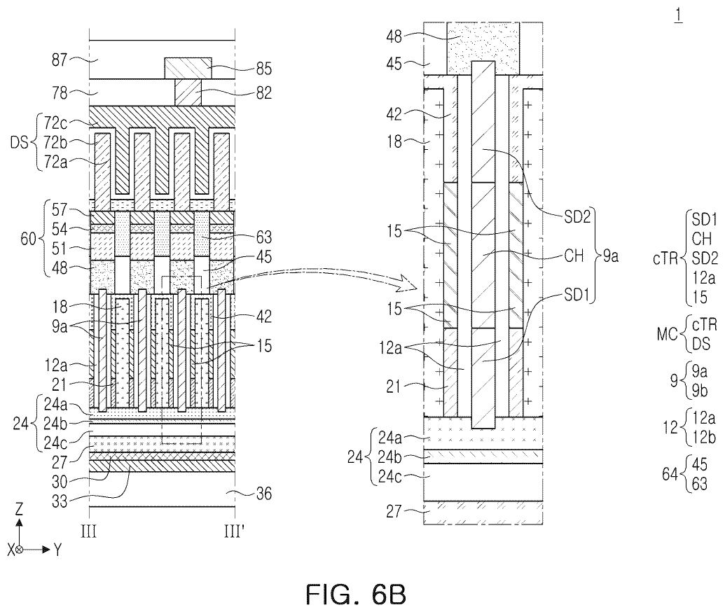

First, examples of the semiconductor device 1 described above will be described together with FIGS. 1 to 3, and FIGS. 5A, 5B, 6A, and 6B. In FIGS. 5A, 5B, 6A, and 6B, FIG. 5A is a plan view illustrating an example of a semiconductor device, FIG. 5B is a partial enlarged view illustrating portion ‘A’ in FIG. 5A, FIG. 6A is a cross-sectional view illustrating regions taken along lines I-I′ and II-II′ in FIG. 5A, and FIG. 6B is a cross-sectional view illustrating a region taken along line III-III′ in FIG. 5A.

Referring to FIGS. 5A, 5B, 6A, and 6B together with FIGS. 1 to 3, as described above, the memory cell array regions MCA and the interface regions IA may be adjacent to each other in the first horizontal direction X. The memory cell array regions MCA and the interface regions IA may include a first interface region IA1, a first memory cell array region MCA1, a second interface region IA2, a second memory cell array region MCA2, and a third interface region IA3, sequentially disposed in the first horizontal direction X.

Hereinafter, among the memory cell array regions MCA, one memory cell array region MCA will be focused on and described.

The semiconductor device 1 may further include active patterns 9, gate electrodes 15, and gate dielectric layers 12. The active patterns 9 may include a semiconductor material that may be used as a channel region of a transistor. For example, each of the active patterns 9 may include at least one of silicon, germanium, silicon-germanium, an oxide semiconductor, or a two-dimensional material layer having semiconductor properties. For example, each of the active patterns 9 may include a semiconductor material such as single crystal silicon or the like.

The active patterns 9 may include cell active patterns 9a and dummy active patterns 9b. The cell active patterns 9a may be disposed in the memory cell array region MCA, and may be arranged in the first horizontal direction X and the second horizontal direction Y. The dummy active patterns 9b may be disposed in the second horizontal direction Y in each of the interface regions IA. The dummy active patterns 9b may be adjacent to the cell active patterns 9a in the first horizontal direction X.

Each of the cell active patterns 9a may include a first source/drain region SD1, a second source/drain region SD2 on the first source/drain region SD1, and a channel region CH between the first and second source/drain regions SD1 and SD2.

The active patterns 9 may have a pillar shape extending in a vertical direction Z, perpendicular to the first and second horizontal directions X and Y. Therefore, the active patterns 9 may also be referred to as active pillars, semiconductor pillars, semiconductor patterns, or channel patterns.

Each of the cell active patterns 9a may be in a bar shape extending in the first horizontal direction X. Each of the dummy active patterns 9b may be in a bar shape extending in the first horizontal direction X. Each of the cell active patterns 9a may be in a tetragonal shape or an elliptical shape elongated in the first horizontal direction X. A width of each of the cell active patterns 9a in the second horizontal direction Y may be substantially the same as a width of each of the dummy active patterns 9b in the second horizontal direction Y.

The cell active patterns 9a may include a first cell active pattern 9a_1 and a second cell active pattern 9a_2, adjacent to each other in the second horizontal direction Y. The dummy active patterns 9b may include a first dummy active pattern 9b_1 and a second dummy active pattern 9b_2, adjacent to each other in the second horizontal direction Y. The first cell active pattern 9a_1 and the first dummy active pattern 9b_1 may be disposed in the first horizontal direction X. The second cell active pattern 9a_2 and the second dummy active pattern 9b_2 may be disposed in the first horizontal direction X.

A length of the first dummy active pattern 9b_1 in the first horizontal direction X may be different from a length of the second dummy active pattern 9b_2 in the first horizontal direction X. For example, the length of the first dummy active pattern 9b_1 in the first horizontal direction X may be greater than the length of the second dummy active pattern 9b_2 in the first horizontal direction X. The length of the first dummy active pattern 9b_1 in the first horizontal direction X may be at least twice as large as the length of the second dummy active pattern 9b_2 in the first horizontal direction X.

The length of the first dummy active pattern 9b_1 in the first horizontal direction X may be greater than a length of each of the cell active patterns 9a in the first horizontal direction X.

The length of the second dummy active pattern 9b_2 in the first horizontal direction X may be substantially equal to the length of each of the cell active patterns 9a in the first horizontal direction X.

The gate electrodes 15 may be the word lines WL (FIG. 3) described above. Each of the gate electrodes 15 may extend in the first horizontal direction X. The gate electrodes 15 may extend across the memory cell array region MCA and into the interface regions IA, and may be adjacent to the active patterns 9. The gate electrodes 15 may face side surfaces of the active patterns 9.

Each of the gate electrodes 15 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi or a combination thereof, but is not limited thereto. Each of the gate electrodes 15 may include a single layer or multiple layers of the above-described conductive materials.

The active patterns 9 may penetrate the gate electrodes 15 in the vertical direction Z. The gate electrodes 15 may surround the side surfaces of the active patterns 9. For example, the gate electrodes 15 may surround side surfaces of the channel regions CH of the cell active patterns 9a.

The gate electrodes 15 may include a first gate electrode 15_1 and a second gate electrode 15_2, adjacent to each other in the second horizontal direction Y. The first cell active pattern 9a_1 and the first dummy active pattern 9b_1 may penetrate the first gate electrode 15_1, and the second cell active pattern 9a_2 and the second dummy active pattern 9b_2 may penetrate the second gate electrode 15_2.

The gate dielectric layers 12 may be disposed on side surfaces of the active patterns 9. Each of the gate dielectric layers 12 may surround a side surface of an active pattern 9 corresponding thereto, among the active patterns 9. The gate dielectric layers 12 may be disposed between the active patterns 9 and the gate electrodes 15. The gate electrodes 15 may be spaced apart from the active patterns 9 by the gate dielectric layers 12. The gate dielectric layers 12 may include cell gate dielectric layers 12a between the cell active patterns 9a and the gate electrodes 15, and dummy gate dielectric layers 12b between the dummy active patterns 9b and the gate electrodes 15.

Each of the cell transistors cTR (FIG. 3) described above may include the first source/drain region SD1, the second source/drain region SD2, the channel region CH, the gate electrode 15 facing the channel region CH, and the cell gate dielectric layer 12a between the gate electrode 15 and the channel region CH.

The channel region CH may extend in the vertical direction Z. Therefore, each of the cell transistors cTR may include the channel region CH extending in the vertical direction Z. Therefore, since an arrangement density of the cell transistors cTR may increase, a degree of integration of the semiconductor device 1 may increase.

In a gate electrode 15 and a cell active pattern 9a, adjacent to each other, among the gate electrodes 15 and the cell active patterns 9a, the gate electrode 15 may surround an entire side surface of the channel region CH of the cell active pattern 9a. Therefore, the cell transistor cTR that may be a vertical channel transistor may be a gate-all-around (GAA) structure transistor that may improve current control capability.

Therefore, the semiconductor device 1 including the cell transistors cTR that may be a vertical channel transistor and a gate-all-around structure transistor may increase a degree of integration, and may improve performance.

The semiconductor device 1 may include conductive patterns 66 that may be the gate contact plugs GC of (FIG. 3) described above. Hereinafter, the conductive patterns 66 will be referred to as gate contact plugs, and will be described.

The gate contact plugs 66 may be connected to the gate electrodes 15 in the interface regions IA. The gate contact plugs 66 may be in contact with and electrically connected to the gate electrodes 15. Each of the gate contact plugs 66 may include at least one of Al, Cu, Ti, Ta, Ru, W, Mo, Pt, Ni, Co, TiN, TaN, WN, NbN, TiAl, TiAlN, or RuTiN.

The semiconductor device 1 may further include an insulating structure 64 and cell contact structures 60.

The gate contact plugs 66 may extend downward through the insulating structure 64, to be in contact with and connected to the gate electrodes 15. The gate contact plugs 66 may extend downward from a portion penetrating the insulating structure 64, may penetrate the second gate capping patterns 42, and may extend into the insulating patterns 18. Upper surfaces of the gate contact plugs 66 may be disposed on substantially the same level as upper surfaces of the cell contact structures 60.

Among the dummy active patterns 9b, dummy active patterns contacting the gate contact plugs 66 may be first dummy active patterns 9b_1, and dummy active patterns not contacting the gate contact plugs 66 may be second dummy active patterns 9b_2. The first dummy active patterns 9b_1 and the second dummy active patterns 9b_2 may be adjacent to each other in the second horizontal direction Y.

The gate contact plugs 66 may be in contact with upper surfaces of the gate electrodes 15, and outer and inner side surfaces of upper regions of the gate electrodes 15. In this case, the inner side surfaces of the gate electrodes 15 may be side surfaces of the gate electrodes 15 facing the first dummy active patterns 9b_1, and the outer side surfaces of the gate electrodes 15 may be side surfaces of the gate electrodes 15 facing the inner side surfaces of the gate electrodes 15.

The gate contact plugs 66 may be in contact with the upper surfaces of the gate electrodes 15, and the outer and inner side surfaces of the upper regions of the gate electrodes 15, to reduce contact resistance between the gate contact plugs 66 and the gate electrodes 15, contacting each other. Therefore, electrical characteristics of the semiconductor device 1 may be improved.

The gate contact plugs 66 may vertically overlap the first dummy active patterns 9b_1. For example, among the gate contact plugs 66, a first gate contact plug 66_1 may vertically overlap the first dummy active pattern 9b_1, and may be connected to the first gate electrode 15_1. The first gate contact plug 66_1 may be in contact with the first dummy active pattern 9b_1, the first gate electrode 15_1, and the dummy gate dielectric layer 12b between the first dummy active pattern 9b_1 and the first gate electrode 15_1. The first gate contact plug 66_1 may be in contact with the first dummy active pattern 9b_1, and may be spaced apart from the second dummy active pattern 9b_2.

Due to the first dummy active patterns 9b_1, the gate contact plugs 66 connected to the gate electrodes 15 may be formed stably and reliably. For example, the first dummy active patterns 9b_1 and the dummy gate dielectric layers 12b may serve as supports stably supporting the gate electrodes 15, and may enable the gate contact plugs 66 to stably contact the gate electrodes 15.

In a region vertically overlapping the gate contact plug 66, an upper end of the dummy gate dielectric layer 12b may be disposed on a level, lower than an upper end of the gate electrode 15 below a lower surface of the gate contact plug 66.

In the region vertically overlapping the gate contact plug 66, a lowermost end of a portion in which the gate contact plug 66 and the first dummy active pattern 9b_1 are in contact may be disposed on a level, higher than the upper end of the gate electrode 15 below the lower surface of the gate contact plug 66.

In the region vertically overlapping the gate contact plug 66, the gate contact plug 66 may be in contact with both side surfaces of an upper region of the gate electrode 15.

Among the gate contact plugs 66, a first gate contact plug 66_1 connected to the first gate electrode 15_1 may be connected to the first gate electrode 15_1 in the second interface region IA2, and a gate contact plug connected to the second gate electrode 15_2 may be connected to the second gate electrode 15_2 in the first interface region IA1. The first gate electrode 15_1 may have an inner side surface facing the first dummy active pattern 9b_1, and an outer side surface opposite to the inner side surface. The first gate contact plug 66_1 may be in contact with an upper surface of the first gate electrode 15_1 and an outer side surface of the first gate electrode 15_1. The first gate contact plug 66_1 may extend between the inner side surface of the first gate electrode 15_1 and the first dummy active pattern 9b_1, such that the first gate contact plug 66_1 may be in contact with the inner side surface of the first gate electrode 15_1 and a side surface of the first dummy active pattern 9b_1.

In an example, upper surfaces of the gate contact plugs 66 may be disposed on a level, higher than a level of upper surfaces of the active patterns 9. For example, an upper surface of the first gate contact plug 66_1 (FIG. 5B) may be disposed on a level, higher than a level of an upper surface of the first cell active pattern 9a_1 (FIG. 5B) and an upper surface of the first dummy active pattern 9b_1 (FIG. 5B).

The semiconductor device 1 may include conductive lines 24 that may be the bit lines BL (FIG. 3) described above. Hereinafter, the conductive lines 24 will be referred to as bit lines. The semiconductor device 1 may further include bit line capping patterns 27 below the bit lines 24.

Each of the bit lines 24 may extend in the second horizontal direction Y, and may cross the memory cell array region MCA. The bit lines 24 may be connected to the cell active patterns 9a below the cell active patterns 9a. For example, the bit lines 24 may be electrically connected to the first source/drain regions SD1 of the cell active patterns 9a. The bit lines 24 may be electrically connected to the first source/drain regions SD1 of the cell transistors cTR. Each of the bit lines 24 may include a first conductive layer 24a, a second conductive layer 24b below the first conductive layer 24a, and a third conductive layer 24c below the second conductive layer 24b. The first conductive layer 24a may include a doped semiconductor material layer. For example, the first conductive layer 24a may include at least one of a silicon layer or a silicon-germanium layer. For example, the first conductive layer 24a may include a polysilicon layer having an N-type conductivity type. The second conductive layer 24b may include at least one of metal, a metal compound, or a metal-semiconductor compound. For example, the second conductive layer 24b may include at least one of Al, Cu, Ti, Ta, Ru, W, Mo, Pt, Ni, Co, TiN, TaN, WN, NbN, TiAl, TiAlN, TiSi, TiSiN, TaSi, CoSi, MoSi, TaSiN, RuTiN, or NiSi. For example, the second conductive layer 24b may include a metal-semiconductor compound layer and a metal compound layer (e.g., a TiN layer, etc.) on the metal-semiconductor compound layer (e.g., a Ti layer, etc.). The third conductive layer 24c may include a conductive material having resistivity, lower than that of the first conductive layer 24a. For example, the third conductive layer 24c may include a conductive material such as W, Mo, Ru, or Ni. The bit line capping patterns 27 may include an insulating material. For example, the bit line capping patterns 27 may include silicon nitride.

The semiconductor device 1 may further include data storage structures DS.

The cell contact structures 60 may be connected to the cell active patterns 9a on the cell active patterns 9a. The cell contact structures 60 may be electrically connected to the second source/drain regions SD2 of the cell active patterns 9a. The cell contact structures 60 may be electrically connected to the second source/drain regions SD2 of the cell transistors cTR. Each of the cell contact structures 60 may be connected to a cell active pattern corresponding thereto, among the cell active patterns 9a. Each of the cell contact structures 60 may be in contact with an upper surface and an upper side surface of a cell active pattern corresponding thereto, among the cell active patterns 9a.

Each of the cell contact structures 60 may include a first conductive layer 48, a second conductive layer 51 on the first conductive layer 48, a third conductive layer 54 on the second conductive layer 51, and a fourth conductive layer 57 on the third conductive layer 54.

The first conductive layer 48 may be an N-type semiconductor layer having a first impurity concentration, and the second conductive layer 51 may be an N-type semiconductor layer having a second impurity concentration, higher than the impurity concentration of the first conductive layer 48. For example, the first conductive layer 48 may be an N-type semiconductor layer having a first impurity concentration, the second conductive layer 51 may be a first doped silicon layer, and the second conductive layer 51 may be a second doped polysilicon layer having a higher impurity concentration than the first doped silicon layer of the first conductive layer 48. The third conductive layer 54 may include a metal-semiconductor compound layer, and the fourth conductive layer 57 may include metal nitride or metal. For example, the third conductive layer 54 may include TiSi, TiSiN, TaSi, TaSiN, MoSi, NiSi, CoSi, or the like. The fourth conductive layer 57 may include at least one of Al, Cu, Ti, Ta, Ru, W, Mo, Pt, Ni, Co, TiN, TaN, WN, NbN, TiAl, TiAlN, or RuTiN.

A maximum width of each of the gate contact plugs 66 may be greater than a maximum width of each of the first conductive layers 48 of the cell contact structures 60.

The data storage structure DS may include first electrodes 72a connected to the cell contact structures 60, second electrodes 72c covering the first electrodes 72a, and a dielectric layer 72b between the first electrodes 72a and the second electrodes 72c. Each of the first electrodes 72a may have a pillar shape extending in the vertical direction Z. The data storage structure DS may be a cell capacitor of a memory such as a DRAM or the like.

The data storage structure DS may be disposed on a level, higher than a level of the cell active patterns 9a. The cell contact structures 60 may electrically connect the cell active patterns 9a and the data storage structure DS between the cell active patterns 9a and the first electrodes 72a of the data storage structure DS.

The semiconductor device 1 may further include insulating patterns 18. The insulating patterns 18 may be disposed between the gate electrodes 15 in the memory cell array region MCA, and may extend into the interface regions IA. The insulating patterns 18 may have lower surfaces disposed on a level, lower than a level of the gate electrodes 15, and upper surfaces disposed on a level, higher than the level of the gate electrodes 15.

The semiconductor device 1 may further include first gate capping patterns 21 disposed below lower surfaces of the gate electrodes 15, and second gate capping patterns 42 disposed on upper surfaces of the gate electrodes 15 and extending onto the upper surfaces of the insulating patterns 18. The first gate capping patterns 21 and the second gate capping patterns 42 may be formed of an insulating material.

The insulating structure 64 may disposed on the side surfaces of the cell contact structures 60 and the gate contact plugs 66. The insulating structure 64 may include a lower insulating layer 45 and an upper insulating layer 63 on the lower insulating layer 45.

An upper surface of the lower insulating layer 45 may be disposed on a level, higher than a level of an upper surface of the first conductive layer 48, but an implementation is not limited thereto. For example, the upper surface of the lower insulating layer 45 may be disposed at substantially the same level as the upper surface of the first conductive layer 48.

The semiconductor device 1 may further include an insulating etch-stop layer 69. The etch-stop layer 69 may be disposed on the cell contact structures 60, the cell contact structures 60, and the gate contact plugs 66. The first electrodes 72a of the data storage structure DS may penetrate the etch-stop layer 69, and may be connected to the cell contact structures 60.

The semiconductor device 1 may further include a first upper insulating layer 78 on the data storage structure DS and the etch-stop layer 69, and a second upper insulating layer 87 on the first upper insulating layer 78.

The semiconductor device 1 may further include first contact plugs 81, second contact plugs 82, first upper interconnections 84, and second upper interconnections 85.

The first contact plugs 81 may penetrate the first upper insulating layer 78 and the etch-stop layer 69, and may be connected to the gate contact plugs 66, and the second contact plugs 82 may penetrate the first upper insulating layer 78, and may be connected to the second electrode 72c of the data storage structure DS. The first upper interconnections 84 may be connected to the first contact plugs 81 on the first upper insulating layer 78, and the second upper interconnection 85 may be connected to the second contact plugs 82 on the first upper insulating layer 78. The second upper insulating layer 87 may cover the first upper insulating layer 78, the first upper interconnections 84, and the second upper interconnection 85.

The semiconductor device 1 may further include an insulating liner 30 covering lower surfaces and side surfaces of the bit lines 24, and covering lower surfaces of the first gate capping patterns 21, lower surfaces of the dummy active patterns 9b, lower surfaces of the gate dielectric layers 12, and lower surfaces of the insulating patterns 18.

The semiconductor device 1 may further include a bit line shield pattern 33 disposed on the side surfaces of the bit lines 24 below the insulating liner 30 and disposed below the lower surface of the bit lines 24. The bit line shield pattern 33 may be formed of a conductive material. Since portions of the bit line shield pattern 33 disposed between the bit lines 24 may reduce parasitic capacitance between the bit lines 24, a signal transmission speed of the bit lines 24 may be suppressed from decreasing.

The semiconductor device 1 may further include a lower capping insulating layer 36 disposed below the bit line shield pattern 33 and the insulating liner 30.

Next, various example implementations that may improve performance or productivity of the semiconductor device 1 will be described. Various example implementations described below and the previously described implementations may be combined with each other to form an example implementation. Hereinafter, the elements described above may be directly cited without a separate detailed description, or description may be omitted. In addition, the elements described below that may be modified or replaced may be described with reference to the drawings below, but the elements that may be modified, replaced, or added may be combined with each other or with the previously described elements to form a semiconductor device.

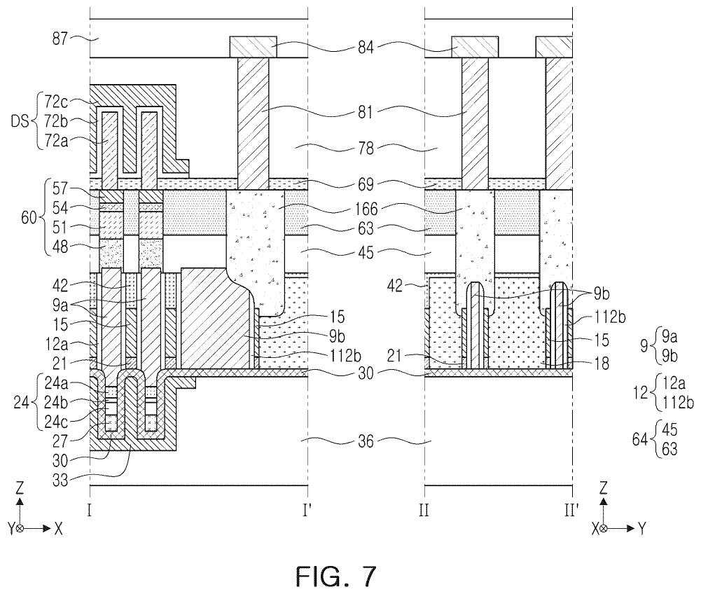

FIG. 7 is a cross-sectional view illustrating an example in which some elements are modified in regions taken along lines I-I′ and II-II′ of FIG. 5A.

In some implementations, referring to FIG. 7, the dummy gate dielectric layer 12b (FIG. 6A) and the gate contact plug 66 (FIG. 6A), described above, may be replaced with a dummy gate dielectric layer 112b and a gate contact plug 166 as in FIG. 7. For example, the gate contact plug 166 may be in contact with an upper surface of the gate electrode 15 and an outer side surface of the gate electrode 15, and the dummy gate dielectric layer 112b may extend between the gate contact plug 166 and the dummy active pattern 9b from a portion disposed between an inner side surface of the gate electrode 15 and the dummy active pattern 9b. In a region vertically overlapping the gate contact plug 166, an upper end of the dummy gate dielectric layer 112b may be disposed on a level, higher than a level of an upper end of the gate electrode 15.

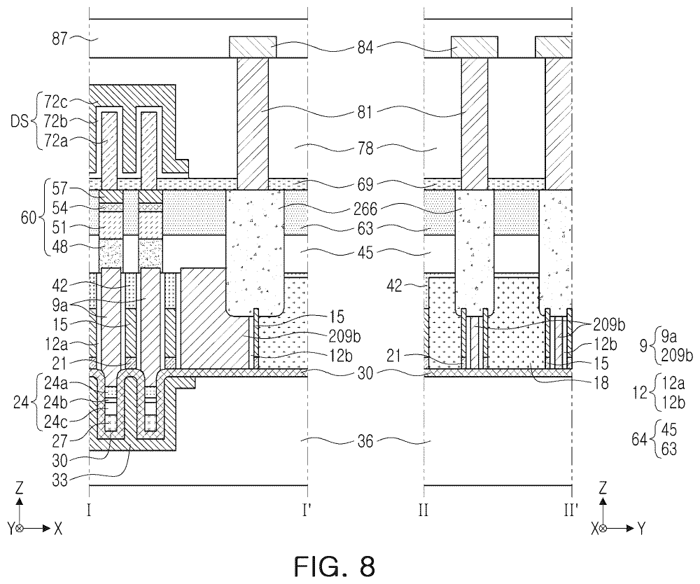

FIG. 8 is a cross-sectional view illustrating an example in which some elements are modified in regions taken along lines I-I′ and II-II′ of FIG. 5A.

In some implementations, referring to FIG. 8, the gate contact plug 66 (FIG. 6A) and the dummy active pattern 9b (FIG. 6A), described above, may be replaced with a gate contact plug 266 and a dummy active pattern 209b as in FIG. 8. For example, in a region vertically overlapping the gate contact plug 266, a lowermost end of a portion in which the gate contact plug 266 and the dummy active pattern 209b are in contact with each other may be disposed on a level, lower than an upper end of the gate electrode 15 located below a lower surface of the gate contact plug 266. An overall volume of the gate contact plug 266 may increase to improve resistance characteristics of the gate contact plug 266.

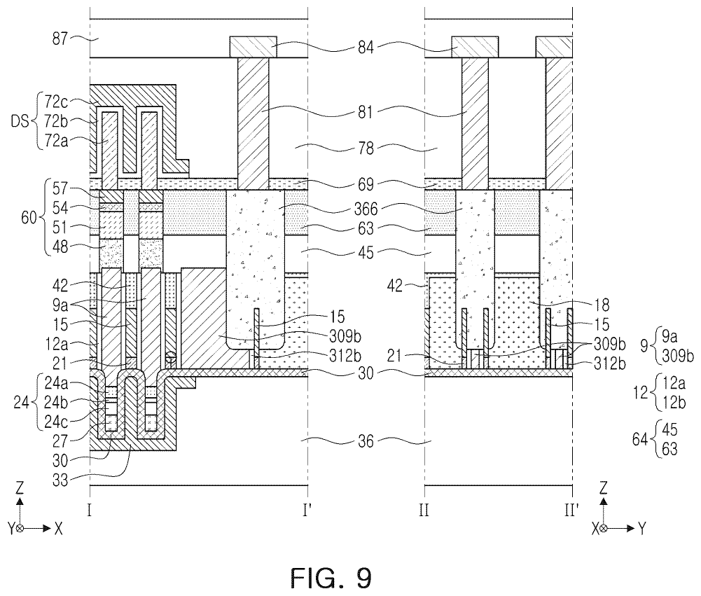

FIG. 9 is a cross-sectional view illustrating an example in which some elements are modified in regions taken along lines I-I′ and II-II′ of FIG. 5A.

In some implementations, referring to FIG. 9, the dummy gate dielectric layer 12b (FIG. 6A), the gate contact plug 66 (FIG. 6A), and the dummy active pattern 9b, described above, may be replaced with a dummy gate dielectric layer 312b, a gate contact plug 366, and a dummy active pattern 309b as in FIG. 9.

The gate contact plug 66 (FIG. 6A) described above may be replaced with the gate contact plug 366 covering both side surfaces of upper and intermediate regions of the gate electrode 15, to increase a contact area with the gate electrode 15. The gate contact plug 366 may extend downward to contact and connect with both side surfaces of at least a portion of a lower region of the gate electrode 15.

In a region vertically overlapping the gate contact plug 366, the gate contact plug 366 may be in contact with inner and outer side surfaces of the upper region of the gate electrode 15. Therefore, since a contact area between the gate contact plug 366 and the gate electrode 15 increases, contact resistance may decrease, such that performance of the semiconductor device 1 may be improved.

In a region vertically overlapping the gate contact plug 366 or below the lower surface of the gate contact plug 366, an upper end of the dummy gate dielectric layer 312b may be disposed on a level, lower than the intermediate region of the gate electrode 15.

In the region vertically overlapping the gate contact plug 366 or below the lower surface of the gate contact plug 366, a lowermost end of a portion in which the gate contact plug 366 and the dummy active pattern 309b are in contact with each other, may be disposed on a level, lower than a level of the intermediate region of the gate electrode 15.

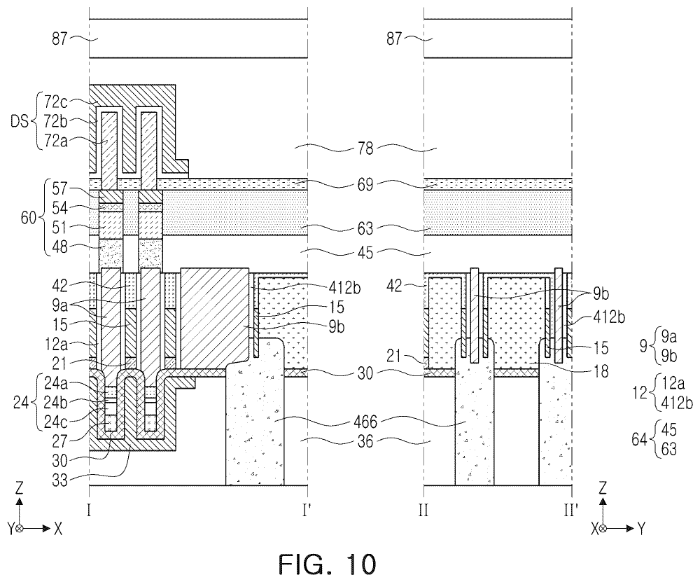

FIG. 10 is a cross-sectional view illustrating an example in which some elements are modified in regions taken along lines I-I′ and II-II′ of FIG. 5A.

In some implementations, referring to FIG. 10, the gate contact plug 66 (FIG. 6A) described above may be replaced with a gate contact plug 466 as in FIG. 10. The dummy gate dielectric layer 12b (FIG. 6A) described above may be replaced with a dummy gate dielectric layer 412b contacting the gate contact plug 466.

The gate contact plug 466 may extend upwardly through the lower capping insulating layer 36, and may be connected to and in contact with the gate electrode 15. The gate contact plug 466 may extend upwardly from a portion penetrating the lower capping insulating layer 36, may penetrate the insulating liner 30, and may be in contact with the dummy active pattern 9b, the insulating pattern 18, and the dummy gate dielectric layer 412b.

In a region vertically overlapping the gate contact plug 466, a lower surface of the dummy gate dielectric layer 412b may be disposed on a level, higher than a level of a lower surface of the gate electrode 15.

In a region vertically overlapping the gate contact plug 466, the gate contact plug 466 may be connected to and in contact with the lower surface of the gate electrode 15, and an inner side surface and an outer side surface of a lower region of the gate electrode 15.

A lower surface of the gate contact plug 466 may be disposed on a level, lower than a level of the bit lines 24. For example, a lower surface of the gate contact plug 466 connected to the first gate electrode 15_1 (FIG. 5B) among the gate electrodes 15 and the first dummy active pattern 9b_1 (FIG. 5B) among the dummy active patterns 9b, in the gate contact plug 466, may be disposed on a level, lower than a level of the bit lines 24.

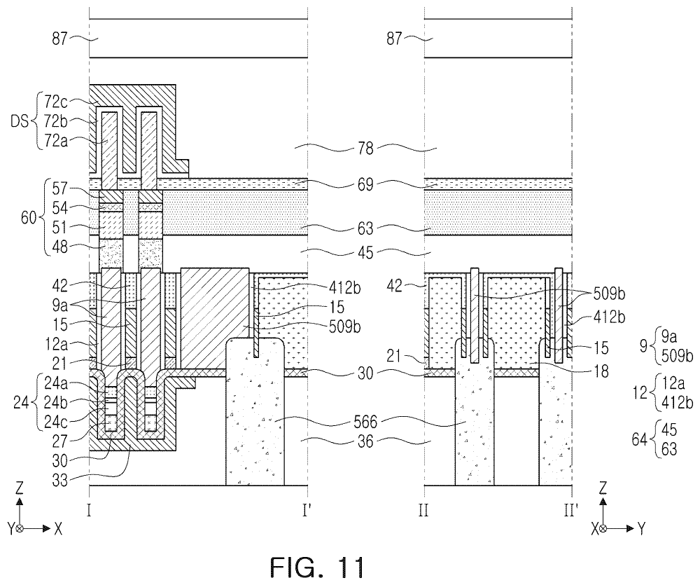

FIG. 11 is a cross-sectional view illustrating an example in which some elements are modified in regions taken along lines I-I′ and II-II′ of FIG. 5A.

In some implementations, referring to FIG. 11, the dummy gate dielectric layer 12b (FIG. 6A) described above may be replaced with the dummy gate dielectric layer 412b described in FIG. 10, the gate contact plug 466 (FIG. 10) described above may be replaced with a gate contact plug 566 described in FIG. 11, and the dummy active pattern 9b (FIG. 6A) described above may be replaced with a dummy active pattern 509b described in FIG. 11.

In a region vertically overlapping the gate contact plug 566, the gate contact plug 566 may be in contact with and connected to a lower surface of the gate electrode 15, and inner and outer side surfaces of the gate electrode 15, as described in FIG. 10.

In the region vertically overlapping the gate contact plug 566, an uppermost end of a portion in which the gate contact plug 566 and the dummy active pattern 509b are in contact with each other may be located on a level, higher than a lower end of the gate electrode 15 located on the gate contact plug 566. An overall volume of the gate contact plug 566 may increase to improve resistance characteristics of the gate contact plug 566.

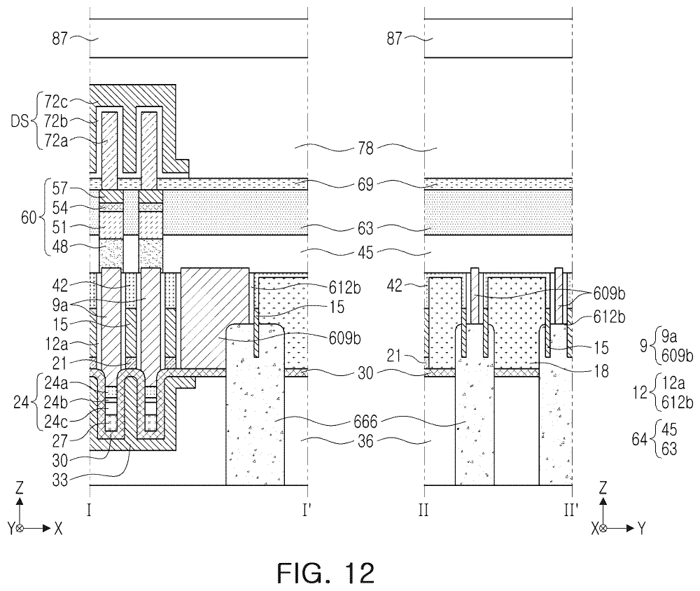

FIG. 12 is a cross-sectional view illustrating an example in which some elements are modified in regions taken along lines I-I′ and II-II′ of FIG. 5A.

In some implementations, referring to FIG. 12, the dummy gate dielectric layer 412b (FIG. 11), the gate contact plug 566 (FIG. 11), and the dummy active pattern 509b (FIG. 11), described in FIG. 11, may be replaced with a dummy gate dielectric layer 612b, a gate contact plug 666, and a dummy active pattern 609b as in FIG. 12.

The gate contact plug (566 of FIG. 11) described above may be replaced with the gate contact plug 666 covering both side surfaces of lower and intermediate regions of the gate electrode 15, to increase a contact area with the gate electrode 15. The gate contact plug 666 may extend upward from a portion covering both side surfaces of the lower and intermediate regions of the gate electrode 15, and may be connected to and in contact with both side surfaces of at least a portion of an upper region of the gate electrode 15. Therefore, since the contact area between the gate contact plug 666 and the gate electrode 15 increases, contact resistance may decrease, and thus performance of the semiconductor device 1 may be improved.

In a region vertically overlapping the gate contact plug 666 or on the gate contact plug 666, a lower end of the dummy gate dielectric layer (612b) may be disposed on a level, higher than a level of an intermediate region of the gate electrode 15.

In the region vertically overlapping the gate contact plug 666 or on the gate contact plug 666, a lowermost end of a portion in which the gate contact plug 666 and the dummy active pattern 609b are in contact with each other, may be disposed on a level, higher than a level of the intermediate region of the gate electrode 15.

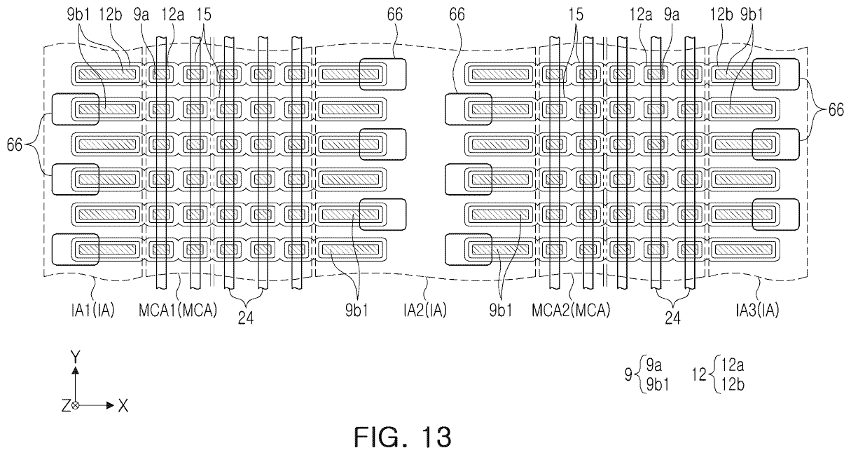

FIG. 13 is a plan view illustrating a modified example of the dummy active patterns 9b (FIGS. 5A and 5B) in the plan view of FIG. 5A.

In some implementations, referring to FIG. 13, the dummy active patterns (FIGS. 5A and 9b) having different lengths in the first horizontal direction X, described above, may be replaced with dummy active patterns 9b1 having the same length in the first horizontal direction X.

In some implementations, the second dummy active pattern 9b_2 (FIG. 5B) described in FIG. 5B may be replaced with a second dummy active pattern having a width and a length, equal to those of the first dummy active pattern 9b_1 (FIG. 5B) described in FIG. 5B. Therefore, each of the dummy active patterns 9b1 may be formed to have a shape and a size, equal to those of the first dummy active pattern 9b_1 (FIG. 5B) described in FIG. 5B.

In another example, the dummy active patterns 9b1 may be formed to have a size, equal to those of the cell active patterns 9a. For example, the dummy active patterns 9b1 and the cell active patterns 9a may have the same length in the first horizontal direction X. In a case in which the dummy active patterns 9b1 is disposed to have a size, equal to those of the cell active patterns 9a, cell active patterns 9a adjacent to the interface region IA, among the cell active patterns 9a (FIG. 13), may be defined as dummy active patterns, and bit lines adjacent to the interface region IA, among the bit lines 24 (FIG. 13), may be omitted.

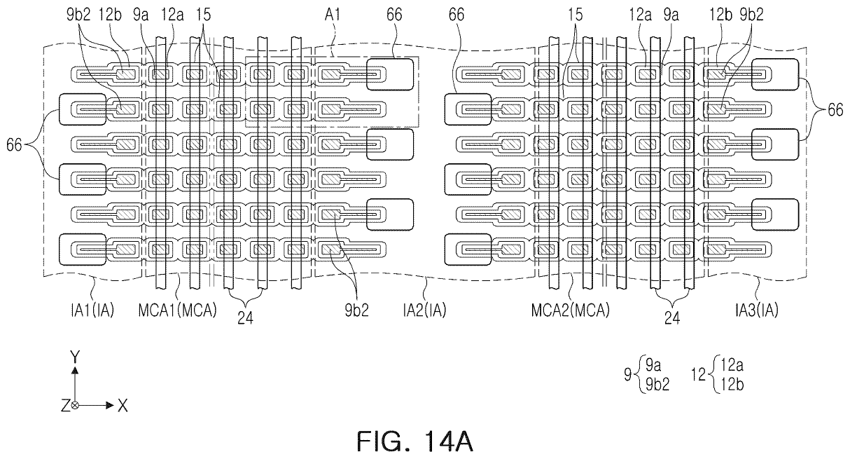

FIG. 14A is a plan view illustrating a modified example of the dummy active patterns 9b1 (FIG. 13) described in the plan view of FIG. 13, and FIG. 14B is a partial enlarged view illustrating portion ‘A1’ of FIG. 14A.

In some implementations, referring to FIGS. 14A and 14B, the dummy active patterns 9b1 (FIG. 13) described in FIG. 13 may be replaced with dummy active patterns 9b2 as in FIGS. 14A and 14B. Each of the dummy active patterns 9b 2 may include a first region 9b2a adjacent to the memory cell array region MCA, and a second region 9b2b extending from the first region 9b2a in a direction, away from the memory cell array region MCA. In this case, the direction away from the memory cell array region MCA may be a direction away from the cell active patterns 9a adjacent to the dummy active patterns 9b2.

In each of the dummy active patterns 9b2, the first region 9b2a may have a width in the second horizontal direction Y that may be substantially equal to a width of each of the cell active patterns 9a in the second horizontal direction Y, and the second region 9b2b may have a width in the second horizontal direction Y that may be smaller than the width of the first region 9b2a in the second horizontal direction Y.

The dummy active patterns 9b2 may include first dummy active patterns 9b2_1 connected to the gate contact plugs 66, and second dummy active patterns 9b2_2 not connected to the gate contact plugs 66.

The gate contact plugs 66 may be connected to and in contact with second regions 9b2b corresponding thereto, among the second regions 9b2b of the first dummy active patterns 9b2_1, and may be spaced apart from the first regions 9b2a of the first dummy active patterns 9b2_1.

The second dummy active patterns 9b2_2 may include the second regions 9b2b to increase a distance between the gate contact plugs 66 and the second dummy active patterns 9b2_2. Therefore, since a width of each of the gate contact plugs 66 in the second horizontal direction Y may increase in a range in which electrical shorts do not occur with the second dummy active patterns 9b2_2, electrical characteristics of the gate contact plugs 66 may be improved.

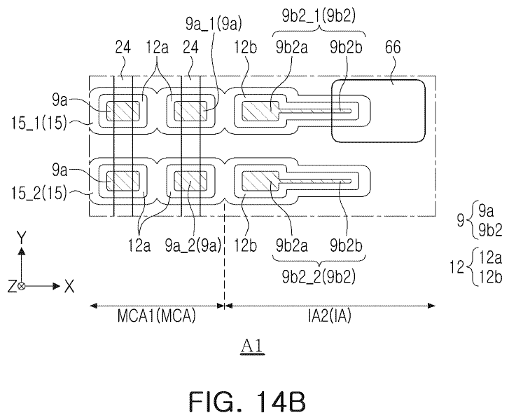

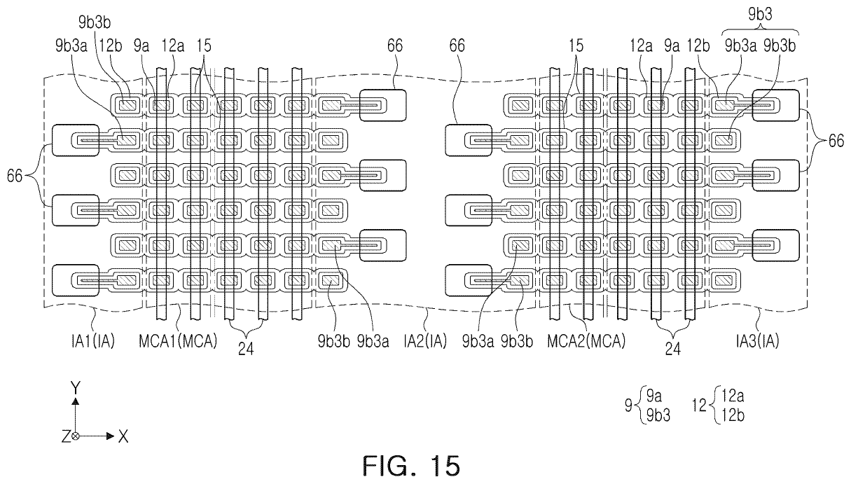

FIG. 15 is a plan view illustrating a modified example of the dummy active patterns 9b2 (FIGS. 14A and 14B) described in the plan view of FIG. 14A.

In some implementations, referring to FIG. 15, the dummy active patterns 9b2 described in FIGS. 14A and 14B may be replaced with dummy active patterns 9b3 as in FIG. 15. The dummy active patterns 9b3 may include first dummy active patterns 9b3a that may be substantially identical to the first dummy active patterns 9b2 (FIGS. 14A and 14B) described in FIGS. 14A and 14B, and second dummy active patterns 9b3b that may be substantially identical to the second dummy active patterns 9b_2 (FIGS. 5A and 5B) that may not be connected to the gate contact plugs 66, as in FIGS. 5A and 5B. The first and second dummy active patterns 9b3a and 9b3b may be spaced apart from the memory cell array region MCA by the same distance. In the first horizontal direction X, a length of each of the first dummy active patterns 9b3a may be greater than a length of each of the second dummy active patterns 9b3b.

The second dummy active patterns 9b3b may be formed with a shorter length than the first dummy active patterns 9b3a, to increase a distance between the gate contact plugs 66 and the second dummy active patterns 9b3b. Therefore, since the width of each of the gate contact plugs 66 in the second horizontal direction Y may increase in a range in which electrical shorts do not occur with the second dummy active patterns 9b3b, electrical characteristics of the gate contact plugs 66 may be improved.

Next, with reference to FIGS. 16A, 16B, 17A, 17B, 18A, 18B, 19A, 19B, 20A, 20B, 21A, and 21B, together with FIG. 5A, an example of a method for forming a semiconductor device will be described. In FIGS. 16A to 20B, FIGS. 16A, 17A, 18A, 19A, 20A, and 21A are cross-sectional views illustrating regions taken along lines I-I′ and II-II′ of FIG. 5A, and FIGS. 16B, 17B, 18B, 19B, 20B, and 21B are cross-sectional views illustrating regions taken along line III-III′ of FIG. 5A.

Referring to FIGS. 5A, 16A, and 16B, a sacrificial substrate 3 and a sacrificial insulating layer 6, sequentially stacked, may be prepared. Active patterns 9 may be formed on the sacrificial insulating layer 6. The active patterns 9 may be formed of a semiconductor material such as single crystal silicon or the like.

The active patterns 9 may include cell active patterns 9a formed in a memory cell array region MCA, and dummy active patterns 9b formed in interface regions IA. The cell active patterns 9a may be disposed in the first horizontal direction X and the second horizontal direction Y. The dummy active patterns 9b may be disposed in the second horizontal direction Y in each of the interface regions IA. The dummy active patterns 9b may be adjacent to the cell active patterns 9a in the first horizontal direction X. A gate dielectric layer 12 conformally covering the sacrificial insulating layer 6 and the active patterns 9 may be formed.

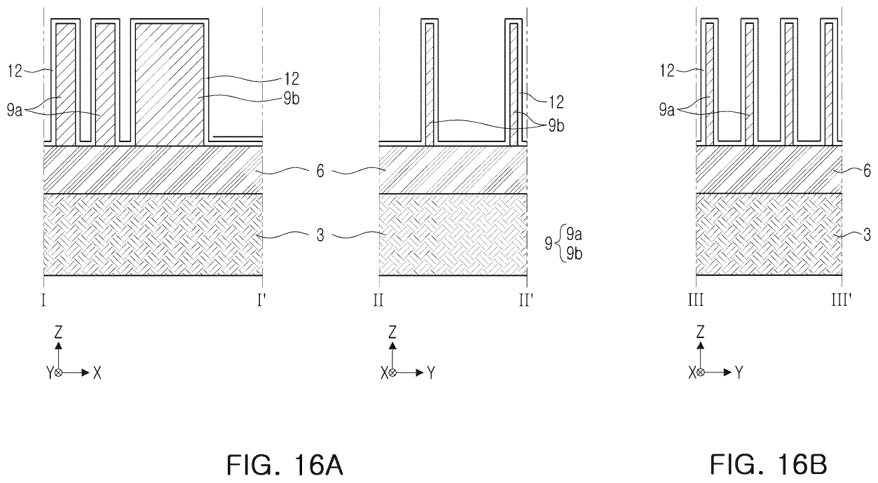

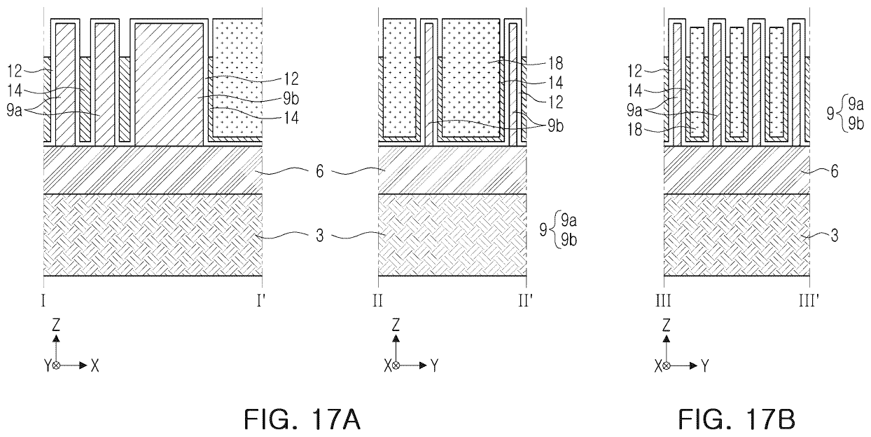

Referring to FIGS. 5A, 17A, and 17B, a conductive layer may be formed on the gate dielectric layer 12, insulating patterns 18 may be formed on the conductive layer, and the conductive layer may be partially etched to form a gate conductive layer 14. The conductive layer for forming the gate conductive layer 14 may cover side surfaces of the active patterns 9, and may fill a space between active patterns 9 adjacent to each other in the first horizontal direction X. A portion of the gate conductive layer 14 may be formed between lower surfaces of the insulating patterns 18 and the gate dielectric layer 12, and an upper surface of the gate conductive layer 14 may be formed on a level, higher than an intermediate portion between lower and upper surfaces of each of the active patterns 9.

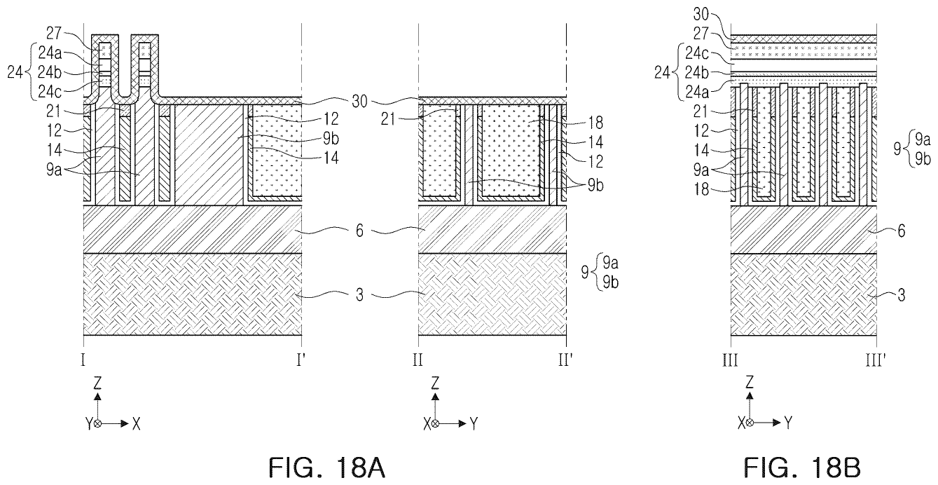

Referring to FIGS. 5A, 18A, and 18B, after forming a bit line conductive layer, the bit line conductive layer may be patterned to form bit lines 24. Each of the bit lines 24 may include a first conductive layer 24a, a second conductive layer 24b, and a third conductive layer 24c, sequentially stacked. While patterning the bit line conductive layer to form the bit line 24, a region not vertically overlapping the bit line 24 may be recessed. An insulating liner 30 conformally covering the bit lines 24 and a region other than the bit lines 24 may be formed.

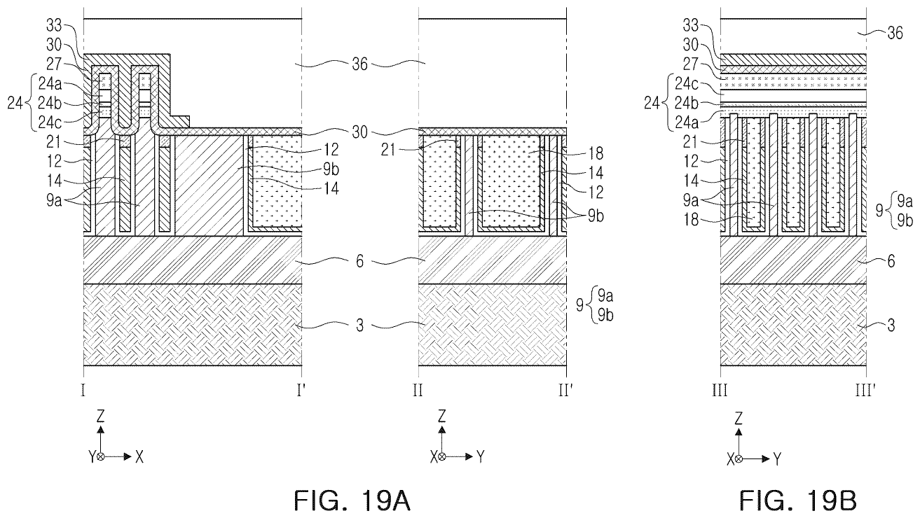

Referring to FIGS. 5A, 19A, and 19B, a bit line shield pattern 33 formed on the insulating liner 30 and filling between the bit lines 24 may be formed. The bit line shield pattern 33 may be formed of a conductive material. The bit line shield pattern 33 may be formed in the memory cell array region MCA, and may be formed in a portion of each of the interface regions IA. The bit line shield pattern 33 may vertically overlap a portion of each of the dummy active patterns 9b. A lower capping insulating layer 36 covering the bit line shield pattern 33 and the insulating liner 30 may be formed.

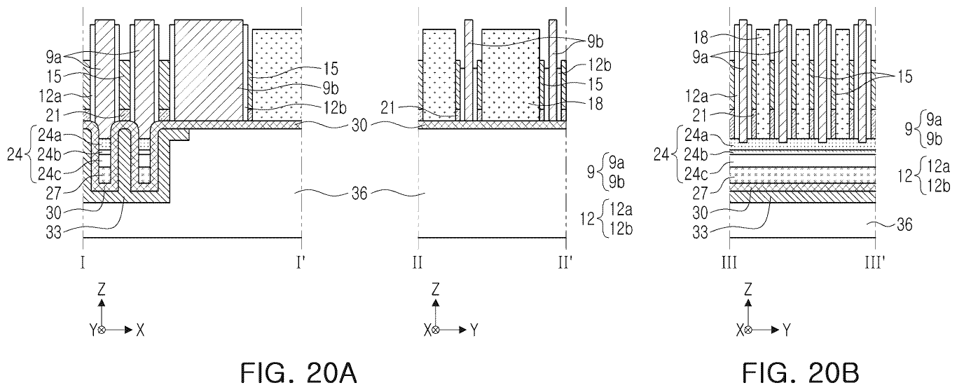

Referring to FIGS. 5A, 20A, and 20B, after the lower capping insulating layer 36 is located to face in a downward direction, the sacrificial substrate 3 and the sacrificial insulating layer 6 may be removed. The gate dielectric layer 12 exposed while removing the sacrificial insulating layer 6 may be partially etched to expose the gate conductive layer 14 (FIGS. 19A and 19B), and the exposed gate conductive layer 14 (FIGS. 19A and 19B) may be partially etched to form gate electrodes 15. Upper surfaces of the gate electrodes 15 may be formed on a level, higher than an intermediate portion between upper and lower surfaces of each of the active patterns 9.

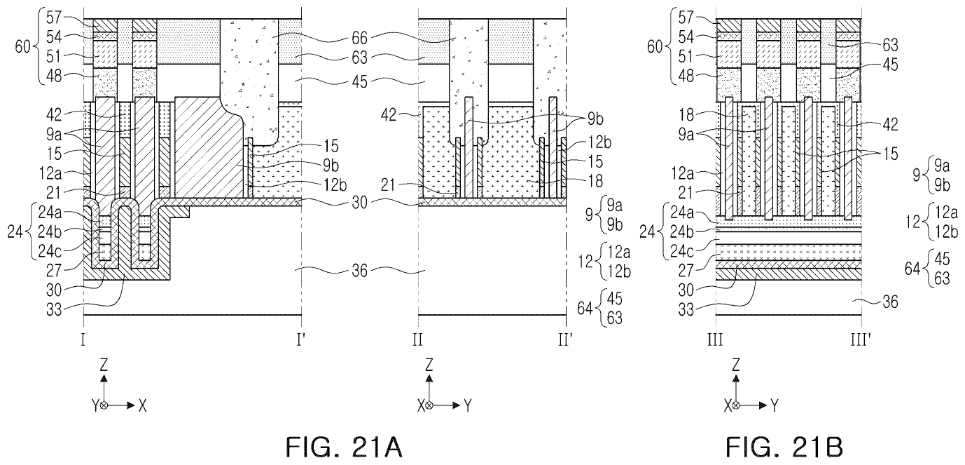

Referring to FIGS. 5A, 21A, and 21B, second gate capping patterns 42 formed on the upper surfaces of the gate electrodes 15 and covering upper surfaces of the insulating patterns 18 may be formed.

Cell contact structures 60 connected to the cell active patterns 9a, gate contact plugs 66 connected to the gate electrodes 15, and insulating structures 64 on side surfaces of the cell contact structures 60 and side surfaces of the gate contact plugs 66 may be formed.

Each of the cell contact structures 60 may include a first conductive layer 48, a second conductive layer 51 on the first conductive layer 48, a third conductive layer 54 on the second conductive layer 51, and a fourth conductive layer 57 on the third conductive layer 54. The gate contact plugs 66 may extend downward through the insulating structure 64 in the interface regions IA to be connected to the gate electrodes 15. The gate contact plugs 66 may be connected while vertically overlapping the dummy active patterns 9b adjacent to the gate electrodes 15 connected to the gate contact plugs 66.

Referring again to FIGS. 5A, 5B, 6A, and 6B, an insulating etch-stop layer 69 may be formed on the cell contact structures 60, the gate contact plugs 66, the cell contact structures 60, and the insulating structure 64. A data storage structure DS may be formed on the insulating etch-stop layer 69. The data storage structure DS may include first electrodes 72a extending upwardly and connected to the cell contact structures 60 through the insulating etch-stop layer 69, a dielectric layer 72b on the first electrodes 72a and the insulating etch-stop layer 69, and a second electrode 72c on the dielectric layer 72b.

A first upper insulating layer 78 covering the data storage structure DS and the insulating etch-stop layer 69 may be formed. First contact plugs 81 and second contact plugs 82 may be formed. The first contact plugs 81 may penetrate the first upper insulating layer 78 and the etch-stop layer 69, and may be connected to the gate contact plugs 66, and the second contact plug 82 may penetrate the first upper insulating layer 78, and may be connected to the second electrode 72c of the data storage structure DS.

First upper interconnections 84 and second upper interconnections 85 may be formed. The first upper interconnections 84 may be connected to the first contact plugs 81 on the first upper insulating layer 78, and the second upper interconnection 85 may be connected to the second contact plug 82 on the first upper insulating layer 78. The first upper insulating layer 78, the first upper interconnections 84, and the second upper interconnections 85 may form a second upper insulating layer 87.

In some implementations, since a vertical channel transistor having a channel region extending in a vertical direction may be provided, a degree of integration of a semiconductor device may increase.

In some implementations, since a gate electrode in a vertical channel transistor may surround an entire side surface of a channel region, performance of the vertical channel transistor may be improved.

In some implementations, active patterns including a cell active pattern electrically connected to a bit line and a data storage structure and a dummy active pattern not electrically connected to the bit line and the data storage structure may be provided. A gate electrode, which may be a word line, may be adjacent to the cell active pattern and the dummy active pattern, and a gate contact plug which may be connected to the gate electrode may be connected to the gate electrode while vertically overlapping the gate electrode and the dummy active pattern adjacent to the gate electrode. The dummy active pattern adjacent to the gate electrode and the gate contact plug may be provided to stably and reliably form the gate contact plug. The gate contact plug may be in contact with at least one of an inner side surface or an outer side surface of the gate electrode. Therefore, since a contact area between the gate contact plug and the gate electrode may increase, contact resistance between the gate plug and the gate electrode may be reduced.

Various advantages and effects of the present disclosure are not limited to the above-described contents, and will be more easily understood in the process of explaining some implementations.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been illustrated and described above, it will be apparent to those skilled in the art that modifications and variations could be made without departing from the scope of the present disclosure as defined by the appended claims.

What is claimed is:

1. A semiconductor device comprising:
a first cell active pattern and a first dummy active pattern, the first cell active pattern and the first dummy active pattern being positioned in a first horizontal direction;
a first gate electrode adjacent to the first cell active pattern and the first dummy active pattern;
a first cell gate dielectric layer between the first cell active pattern and the first gate electrode;
a first dummy gate dielectric layer between the first dummy active pattern and the first gate electrode;
a first gate contact plug contacting the first dummy active pattern and the first gate electrode; and
a bit line disposed lower than the first cell active pattern, the bit line being connected with the first cell active pattern and spaced apart from the first dummy active pattern.

2. The semiconductor device of claim 1, wherein, in the first horizontal direction, a length of the first dummy active pattern is greater than a length of the first cell active pattern.

3. The semiconductor device of claim 2, wherein, in a second horizontal direction, perpendicular to the first horizontal direction, a width of the first dummy active pattern is substantially a same as a width of the first cell active pattern.

4. The semiconductor device of claim 2, wherein the first dummy active pattern includes a first region and a second region, the second region extending from the first region in a direction away from the first cell active pattern,
wherein a width of the first region is substantially a same as a width of the first cell active pattern in a second horizontal direction perpendicular to the first horizontal direction, and
wherein a width of the second region is smaller than the width of the first region in the second horizontal direction.

5. The semiconductor device of claim 4, wherein the first gate contact plug contacts the second region and is spaced apart from the first region.

6. The semiconductor device of claim 1, further comprising
a data storage structure disposed higher than the first cell active pattern; and
a cell contact structure electrically connecting the data storage structure and the first cell active pattern, the cell contact structure being between the data storage structure and the first cell active pattern.

7. The semiconductor device of claim 6, wherein the first cell active pattern includes a first source/drain region, a second source/drain region on the first source/drain region, and a channel region between the first source/drain region and the second source/drain region,
wherein the bit line is connected with the first source/drain region of the first cell active pattern, and
wherein the cell contact structure is connected with the second source/drain region of the first cell active pattern.

8. The semiconductor device of claim 7, wherein the first gate electrode surrounds a side surface of the channel region of the first cell active pattern, and
wherein the first cell gate dielectric layer is between the side surface of the channel region of the first cell active pattern and the first gate electrode.

9. The semiconductor device of claim 1, wherein the first gate electrode has an inner side surface and an outer side surface, the inner side surface facing the first dummy active pattern, and the outer side surface opposite to the inner side surface,
wherein an upper surface of the first gate contact plug is disposed higher than an upper surface of the first cell active pattern and an upper surface of the first dummy active pattern, and
wherein the first gate contact plug contacts an upper surface of the first gate electrode and the outer side surface of the first gate electrode.

10. The semiconductor device of claim 9, wherein the first gate contact plug extends between the inner side surface of the first gate electrode and the first dummy active pattern, and the first gate contact plug contacts the inner side surface of the first gate electrode.

11. The semiconductor device of claim 1, wherein the first gate electrode has an inner side surface and an outer side surface, the inner side surface facing the first dummy active pattern, and the outer side surface opposite to the inner side surface,
wherein a lower surface of the first gate contact plug is disposed lower than the bit line, and
wherein the first gate contact plug contacts a lower surface of the first gate electrode and the outer side surface of the first gate electrode.

12. The semiconductor device of claim 11, wherein the first gate contact plug extends between the inner side surface of the first gate electrode and the first dummy active pattern, and the first gate contact plug contacts the inner side surface of the first gate electrode.

13. The semiconductor device of claim 1, further comprising:
a second cell active pattern and a second dummy active pattern, the second cell active pattern and the second dummy active pattern being positioned in the first horizontal direction;
a second gate electrode adjacent to the second cell active pattern and the second dummy active pattern;
a second cell gate dielectric layer between the second cell active pattern and the second gate electrode; and
a second dummy gate dielectric layer between the second dummy active pattern and the second gate electrode,
wherein the second cell active pattern and the first cell active pattern are adjacent to each other in a second horizontal direction perpendicular to the first horizontal direction,
wherein the second dummy active pattern and the first dummy active pattern are adjacent to each other in the second horizontal direction, and
wherein the bit line extends, in the second horizontal direction, from a portion connected to the first cell active pattern to the second cell active pattern.

14. The semiconductor device of claim 13, wherein, in the first horizontal direction, a length of the first dummy active pattern is greater than a length of the first cell active pattern, a length of the second cell active pattern, and a length of the second dummy active pattern.

15. The semiconductor device of claim 13, wherein, in the first horizontal direction, a length of the first dummy active pattern is greater than a length of the first cell active pattern and a length of the second cell active pattern, and a length of the second dummy active pattern is greater than the length of the first cell active pattern and the length of the second cell active pattern.

16. A semiconductor device comprising:
a memory cell array region and an interface region adjacent to each other in a first horizontal direction;
a plurality of gate electrodes extending in the first horizontal direction, crossing the memory cell array region, and extending into the interface region;
a plurality of active patterns including a plurality of cell active patterns and a plurality of dummy active patterns, the plurality of cell active patterns being disposed in the memory cell array region and positioned along the first horizontal direction and a second horizontal direction perpendicular to the first horizontal direction, and the plurality of dummy active patterns being disposed in the interface region and positioned along the second horizontal direction;
a plurality of gate dielectric layers interposed between the plurality of gate electrodes and the plurality of active patterns;
a plurality of bit lines extending in the second horizontal direction, crossing the memory cell array region, and connected with the plurality of cell active patterns below the plurality of cell active patterns; and
a plurality of gate contact plugs disposed in the interface region,
wherein the plurality of active patterns extend into the plurality of gate electrodes in a vertical direction perpendicular to the first horizontal direction and the second horizontal direction,
wherein a first gate electrode of the plurality of gate electrodes is adjacent to a first dummy active pattern of the plurality of dummy active patterns, and
wherein a first gate contact plug of the plurality of gate contact plugs vertically overlaps the first dummy active pattern and contacts the first gate electrode.

17. The semiconductor device of claim 16, wherein the plurality of gate dielectric layers include a first dummy gate dielectric layer between the first dummy active pattern and the first gate electrode, and
wherein the first gate contact plug contacts the first dummy active pattern and the first dummy gate dielectric layer.

18. The semiconductor device of claim 16, wherein, in the first horizontal direction, each cell active pattern of the plurality of cell active patterns has a first length, and the first dummy active pattern has a second length greater than the first length.

19. A semiconductor device comprising:
a memory cell array region and an interface region adjacent to each other in a first horizontal direction;
a plurality of gate electrodes extending in the first horizontal direction, crossing the memory cell array region, and extending into the interface region;
a plurality of bit lines extending in a second horizontal direction perpendicular to the first horizontal direction and crossing the memory cell array region;
a plurality of active patterns extending into the plurality of gate electrodes in a vertical direction perpendicular to the first horizontal direction and the second horizontal direction, the plurality of active patterns including a plurality of cell active patterns disposed in the memory cell array region and a plurality of dummy active patterns disposed in the interface region;
a plurality of gate dielectric layers between the plurality of active patterns and the plurality of gate electrodes; and
a plurality of gate contact plugs connected with the plurality of gate electrodes,
wherein the plurality of dummy active patterns include a first dummy active pattern and a second dummy active pattern adjacent to each other in the second horizontal direction,
wherein the first dummy active pattern has a length in the first horizontal direction greater than a length of each cell active pattern of the plurality of cell active patterns in the first horizontal direction,
wherein the length of the first dummy active pattern in the first horizontal direction is greater than a length of the second dummy active pattern in the first horizontal direction, and
wherein a first gate contact plug of the plurality of gate contact plugs contacts a first gate electrode of the gate electrodes.

20. The semiconductor device of claim 19, wherein the first gate electrode is adjacent to the first dummy active pattern,
wherein the first gate electrode has an inner side surface and an outer side surface, the inner side surface facing the first dummy active pattern, and the outer side surface opposite to the inner side surface,
wherein the first gate contact plug contacts at least one of the inner side surface or the outer side surface of the first gate electrode, and
wherein the first dummy active pattern contacts the first gate contact plug.
